(19) United States
(12) Patent Application Publication
(10) Pub. No.: US 2024/0153775 A1
(43) Pub. Date: May 9, 2024

(54) PLASMA ASSISTED DAMAGE ENGINEERING DURING ION IMPLANTATION

(71) Applicant: Applied Materials, Inc., Santa Clara, CA (US)

(72) Inventors: Christopher R. Hatem, Seabrook, NH (US); Michael Noel Kennedy, Boston, MA (US); Edmund G. Seebauer, Urbana, IL (US)

(73) Assignee: Applied Materials, Inc., Santa Clara, CA (US)

(21) Appl. No.: 17/980,905

(22) Filed: Nov. 4, 2022

(51) Int. Cl. H01L 21/265; H01L 21/02; H01L 21/324

(52) U.S. Cl. CPC H01L 21/26513; H01L 21/02049; H01L 21/324; H01J 37/3171

(57) ABSTRACT

A method of method of treating a semiconductor substrate. The method may include, in a beamline ion implanter, exposing a substrate surface of the semiconductor substrate to a plasma clean and exposing the substrate surface to a hydrogen treatment from a plasma source. The method may further include, in the beamline ion implanter, exposing the substrate to an implant process after formation of the hydrogen passivation, wherein the substrate is maintained under vacuum over a process duration spanning the plasma clean, the hydrogen treatment, and the implant process.

### FIELD

The present embodiments relate to implant damage engineering in a semiconductor substrate, and more particularly plasma assisted processing in beamline ion implantation.

### BACKGROUND

As semiconductor devices such as logic and memory devices continue to scale to smaller dimensions, the use of conventional processing and materials to fabricate semiconductor devices is increasingly problematic. In one example, known ion implantation processing may create undue damage that is problematic for fabrication of transistors formed of three-dimensional structures, such as horizontal gate all around structures (HGAA) where active regions are formed using so-called nanowires. In the case of ion implantation of dopants, achieving a very high dopant activation and shallow junction depth while minimizing implant damage are all useful. Similarly, in the case of pre amorphization implantation (PAI), minimizing residual substrate damage after recrystallization of an amorphous layer may be useful.

With respect to these and other considerations the present disclosure has been provided.

### SUMMARY

This Summary is provided to introduce a selection of concepts in a simplified form further described below in the Detailed Description. This Summary is not intended to identify key features or essential features of the claimed subject matter, nor is the summary intended as an aid in determining the scope of the claimed subject matter.

In one embodiment, a method of treating a substrate may include, in a beamline ion implanter exposing a substrate surface of the semiconductor substrate to a plasma clean, and exposing the substrate surface to a hydrogen treatment from a plasma source. The method may further include, in the beamline implanter, exposing the substrate to an implant process after the hydrogen treatment. The substrate may be maintained under vacuum over a process duration spanning the plasma clean, the hydrogen treatment, and the implant process.

In another embodiment, a method of doping a substrate is provided. The method may include providing a monocrystalline semiconductor material on a surface of the substrate, exposing the substrate surface to a hydrogen treatment from a plasma source a beamline ion implanter, and exposing the substrate to an implant process in the beamline ion implanter after the hydrogen treatment. As such, the implant process may introduce a dopant species into the substrate, wherein the substrate is maintained under vacuum over a process duration spanning the hydrogen treatment, and the implant process.

In a further embodiment, a beamline ion implantation system is provided. The beamline ion implantation system may include an ion source, to generate an ion beam, a beamline to conduct the ion beam to an end station; a substrate platen to support a substrate while in the end station; and a plasma source, communicatively coupled with the end station and arranged to direct a hydrogen species to the substrate.

### BRIEF DESCRIPTION OF THE DRAWINGS

FIGS. 1A-1C illustrate exemplary operations involved in processing a substrate according to embodiments of the disclosure;

FIGS. 2A-2D illustrate exemplary operations involved in processing a substrate according to further embodiments of the disclosure;

FIG. 3A and FIG. 3B present experimental results showing the effect on dopant profile and residual damage on a semiconductor substrate, respectively, caused by processing a substrate according to the present embodiments;

FIG. 3C presents experimental electron microscopy analysis showing the effect of processing a substrate according to the present embodiments on the solid phase epitaxial regrowth in the substrate;

FIG. 4 illustrates an exemplary ion implanter according to some embodiments of the disclosure;

FIG. 5 presents a histogram graph that depicts a comparison of residual substrate damage after ion implantation for substrates implanted with the same total ion dose, under different processing cycle conditions; and

FIG. 6 depicts an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

In the present embodiments, the present inventors have identified novel approaches to promote improved defect control and reduce post-implantation defectivity for implanted semiconductor substrates, such as monocrystalline semiconductor material. In various non-limiting embodiments, suitable semiconductor structures include silicon, silicon-germanium alloys (SiGe), or silicon-phosphorous alloys. The approaches as detailed below may be generally referred to as plasma assisted damage engineering, where plasma processes are performed in conjunction with ion implantation.

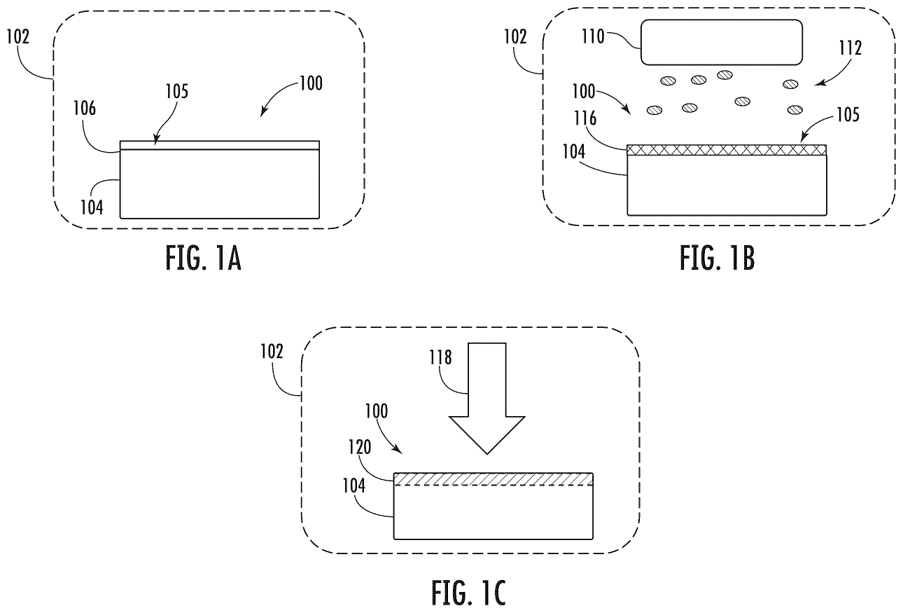

FIGS. 1A-1C illustrate exemplary operations involved in processing a substrate according to embodiments of the disclosure. Turning in particular to FIG. 1A, there is shown a first instance where a semiconductor substrate 100 is provided in an ion implantation apparatus 102 or system. The ion implantation apparatus 102 may represent a beamline ion implanter in some non-limiting embodiments, or other apparatus suitable to perform ion-implantation. The ion implantation apparatus 102 may include one or more chambers or locations that house the semiconductor substrate 100 during various processes to be performed.

While the semiconductor substrate 100 is located within the ion implantation apparatus 102, it may be understood that high vacuum conditions are maintained. For example, during ion implantation of the semiconductor substrate 100, vacuum levels of less than 10-3 ton may be maintained in the end station housing the semiconductor substrate 100. During other processing operations, such as plasma-based operations, the vacuum levels of less than 10-1 ton may be maintained, while during idle periods, vacuum levels of less than 10-4 ton may be maintained according to non-limiting embodiments of the disclosure. Furthermore, exposure to ambient gaseous species outside of the ion implantation apparatus 102 may be precluded during the operations shown in FIG. 1A-FIG. 1C. In FIG. 1A the semiconductor substrate 100 may represent a monocrystalline semiconductor substrate, such as silicon, silicon-germanium alloy (SiGe), Si—P alloy, or other known semiconductor.

Note that during processing of a monocrystalline semiconductor substrate, an oxide layer may be present or may form on an outer surface of the monocrystalline semiconductor substrate. At the stage represented in FIG. 1A, the semiconductor substrate 100 may be placed into the ion implantation apparatus 102, after having received processing through multiple operations in order to synthesize devices, such as logic devices, memory devices, or other devices to receive implantation processing for the purposes of doping. In the example shown, the semiconductor substrate 100 includes a substrate base 104, formed of monocrystalline semiconductor material. In some embodiments, the semiconductor substrate 100 may also include a native oxide layer 106, disposed on an outer surface of the semiconductor substrate 100, such as a first main surface, which surface is designated by the substrate surface 105. As depicted in FIG. 1A the substrate base 104 and native oxide layer 106 may represent any suitable portion of a semiconductor substrate, including patterned regions of a semiconductor device, such as source/drain regions, according to various embodiments of the disclosure. The native oxide layer 106 may represent that layer forming after processing to remove any other materials from the surface of the substrate base 104. The formation of native oxide on silicon and like semiconductors in well-known and will not be discussed in detail herein. However, even when monocrystalline silicon is processed to remove any oxide or other non-silicon material from an outer surface, a native oxide may tend to form upon exposure to oxygen-containing (including water vapor) atmosphere, such as the ambient outside of a vacuum processing tool. Moreover, native oxide tends to be self-limiting in thickness, such that the thickness of the native oxide layer 106 may be assumed to be no more than 4 nm-8 nm in some non-limiting embodiments.

Turning now to FIG. 1B, there is shown an operation of exposing the substrate surface 105 of the semiconductor substrate 100 to a hydrogen treatment operation, also referred to as a hydrogen treatment. Initially, the substrate surface 105 may be covered with up to several nm of native oxide, as represented by the native oxide layer 106. In some embodiments, the hydrogen treatment operation may employ a plasma source 110 that is located in the ion implantation apparatus 102. The plasma source 110 may represent any suitable apparatus to generate a plasma, and in some instances may represent a radical source. In any case, the plasma source 110 may generate hydrogen species 112, which species may represent a combination of ions and neutrals, energetic neutrals, including radicals.

In the case of the hydrogen species 112 including ions or energetic neutrals, during the hydrogen treatment, the energy of the ions and neutrals may be maintained below 100 eV, such as in the range of several eV to 50 eV in some non-limiting embodiments. At this relatively lower energy, the hydrogen species 112 may selectively etch the native oxide layer 106 with respect to the substrate base 104. As such, the native oxide layer 106 may be removed from the substrate base 104 with little or no etching of the substrate base 104, and little or no damage to the substrate base 104, due to the low energy of the hydrogen species 112 as well as the low mass of the hydrogen species 112.

In particular embodiments, the hydrogen treatment may include generating a hydrogen species 112 in a plasma chamber of the plasma source 110, and directing the hydrogen species 112 to the substrate surface 105 when the substrate is at a treatment temperature below 100° C., such as between room temperature and 100° C. The hydrogen species may be generated by providing an H₂ gas for example to a plasma chamber. As such, the substrate surface 105 may represent a ‘clean’ semiconductor surface that presents silicon species to the ambient within ion implantation apparatus 102, with minimal or no foreign species such as oxygen or carbon on the substrate surface 105. Moreover, after removal of the native oxide, the hydrogen species may cause the substrate surface 105 to be terminated with hydrogen bonded to the semiconductor substrate 100, shown as a hydrogen passivation layer, or hydrogen passivation 116. As used herein, the term hydrogen passivation may refer to hydrogen species that stabilize silicon material at the silicon surface from chemical reactions through the creation of hydrogen-silicon bonds.

Turning now to FIG. 1C, there is shown a subsequent instance where the semiconductor substrate 100 is exposed to an implant process on the substrate surface 105, after formation of the hydrogen passivation 116. According to various embodiments of the disclosure, the semiconductor substrate100 is maintained under vacuum over a process duration spanning the hydrogen treatment, and the implant process. Note that ion species 118 provided for the implant may be provided as an ion beam in a beamline ion implanter for example. In some examples the ion species 118 may be provided as an analyzed ion beam. In various embodiments, the ion species 118 may be a dopant element that is implanted into the semiconductor substrate 100 to dope the substrate, such as boron, phosphorous, arsenic, and so forth.

According to some embodiments, the implant process as illustrated in FIG. 1C may be an amorphizing implant that generates an amorphous layer extending below the substrate surface 105. In some embodiments, the implant process of FIG. 1C may be a pre-amorphizing implant, where the ion species 118 may be used to generate an amorphous layer in the substrate 100. As such, the ion species 118 need not be dopant species, and may include species such as inert gas ions, or other non-dopant ions, for example.

In particular embodiments where the ion species 118 are used for a pre-amorphizing implant, a further ion implantation process may follow that process of FIG. 1C to introduce dopant into the substrate 100, for example. In this manner, the dopant implantation may implant species into the semiconductor substrate 100 while an amorphous layer is present. As such, the amorphous layer may act to prevent undue channeling of dopant ions during implantation, and may result in a more desirable dopant profile, after a subsequent activation anneal procedure is performed.

In any of the different scenarios for the implantation procedure depicted in FIG. 1C, an altered layer 120 is formed in the substrate 100, as a result of implantation of the ion species 118. Thus, the altered layer 120 may represent a doped region of the substrate 100, an amorphized region of the substrate 100, or other altered region. In accordance with embodiments of the disclosure, the properties of the altered layer 120, as well as regions is the semiconductor substrate 100 subsequently formed from the altered layer 120, are at least in part determined by the hydrogen treatment shown in FIG. 1B.

Note that the ion dose and the ion energy of ion species 118 may be chosen at a suitable dose and ion energy according to the type of implant being performed and the targeted substrate properties. For example, for some dopant applications, such as boron or phosphorous implantation, the ion energy may range between 500 eV and 7 keV. For pre-amorphizing implantation, the ion dose and ion energy may be chosen to generate an amorphous layer of a targeted thickness, but in some applications may be less than 10 keV.

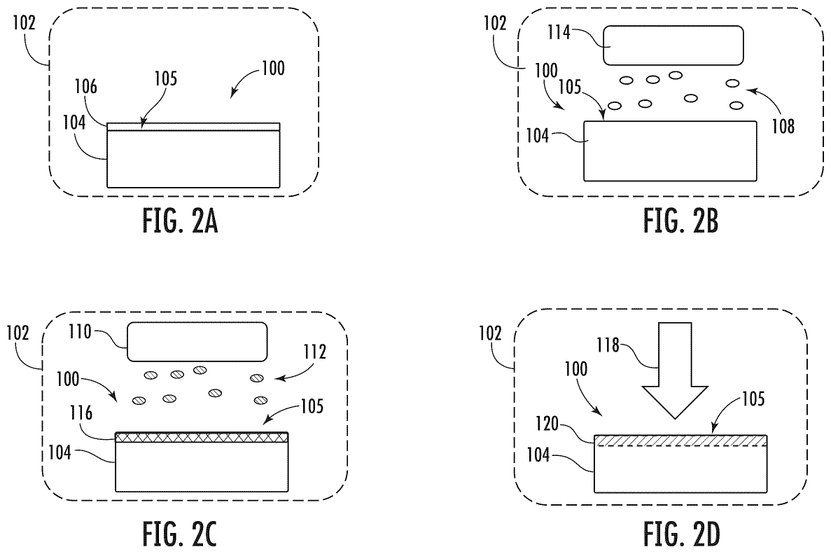

FIGS. 2A-2D illustrate exemplary operations involved in processing a substrate according to embodiments of the disclosure. Turning in particular to FIG. 2A, the scenario may be similar to the stage depicted in FIG. 1A, where like elements are labeled the same, as discussed previously. Turning to FIG. 2B, there is shown a subsequent instance where the substrate surface 105 of semiconductor substrate 100 is exposed to a plasma clean operation. Initially, the substrate surface 105 may be covered with by the native oxide layer 106, discussed previously. In some embodiments, the plasma clean operation may employ a plasma source 114 that is located the ion implantation apparatus 102. The plasma source 114 may represent any suitable apparatus to generate a plasma, and in some instances may represent a radical source. In any case, the plasma source 114 may generate cleaning species 108, which species may represent a combination of ions and neutrals, including radicals.

In the case of the cleaning species 108 including ions, during the plasma clean operation, the energy of the ions may be maintained below 100 eV, such as in the range of several eV to 30 eV in some non-limiting embodiments. In some embodiments, the cleaning species 108 may represent known reactive species that tend to chemically react to etch the native oxide layer 106, even when the energy of such reactive species is on the order of several eV. In various embodiments, the cleaning species 108 may selectively etch the native oxide layer 106 with respect to the substrate base 104. As such, plasma source 114 may act as a plasma etch source to remove the native oxide layer 106 from the substrate base 104 with little or no etching of the substrate base 104, and little or no damage to the substrate base 104, due to the low energy of the cleaning species 108.

According to some embodiments, the plasma clean operation of FIG. 2B may be accomplished by generating hydrogen species in a plasma chamber of plasma source 110, and directing the hydrogen species to the substrate surface 105 when the substrate is at a cleaning temperature between room temperature and 100° C. The hydrogen species may be generated by providing an H₂ gas for example to a plasma chamber. As such, the substrate surface 105 may represent a ‘clean’ semiconductor surface that presents silicon species to the ambient within ion implantation apparatus 102, with minimal or no foreign species such as oxygen or carbon on the substrate surface 105. An advantage of using non-hydrogen species to perform the plasma clean operation of FIG. 2B is that the non-hydrogen species may be chosen to provide a more rapid removal of the native oxide layer 106. For example, according to some non-limiting embodiments, a highly selective and isotropic plasma clean using a mixture of NF₃/NH₃ may be performed as a plasma clean to remove an oxide layer, or alternatively an ion sputtering clean may be used as the plasma clean.

Turning now to FIG. 2C, there is shown an operation of exposing the substrate surface 105 of the semiconductor substrate 100 to a hydrogen treatment operation, also referred to as a hydrogen treatment. As with the embodiment of FIG. 1B, the hydrogen treatment operation may employ a plasma source 110 that is located in the ion implantation apparatus 102, in order to generate hydrogen species 112, which species may represent a combination of ions and neutrals, energetic neutrals, including radicals.

Note that in various embodiments, the hydrogen treatment of FIG. 2C may employ a different plasma chemistry than the plasma clean operation of FIG. 2B, and may optionally be performed using a different plasma source (plasma source 110) than plasma source 114, used to perform the plasma cleaning operation. Moreover, because the operation of FIG. 2C follows the plasma clean operation of FIG. 2B, most or all of the native oxide layer 106 may be absent at the time of the hydrogen treatment operation. In any case, the plasma source 110 may generate hydrogen species 112, which species may represent a combination of ions and neutrals, energetic neutrals, including radicals. As such, like the embodiment of FIG. 2Bm, the hydrogen species112 may cause the substrate surface 105 to be terminated with hydrogen bonded to the semiconductor substrate 100, shown as a hydrogen passivation layer, or hydrogen passivation 116.

Turning now to FIG. 2D, there is shown a subsequent instance where the semiconductor substrate 100 is exposed to an implant process on the substrate surface 105, after formation of the hydrogen passivation 116. This procedure may be generally the same as that procedure of FIG. 1C and will not be discussed further herein.

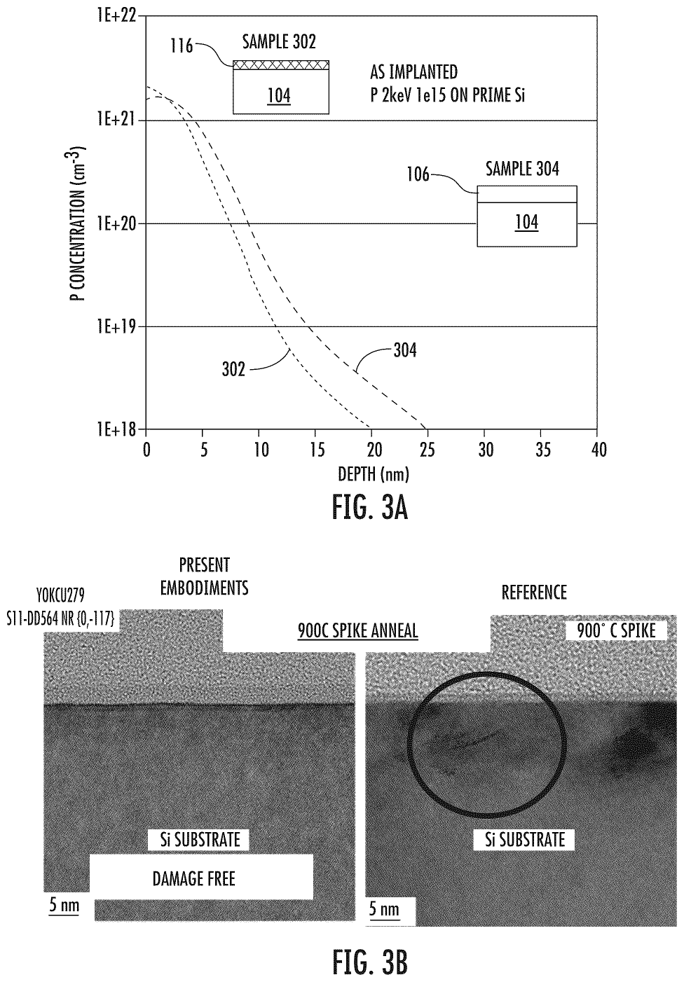

To illustrate advantages afforded by the present embodiments, in FIG. 3A, there is shown a comparison of a dopant profile for a sample that is implanted according to the present embodiments, and a sample implanted according to a known procedure. The curve 302 represents a dopant profile for a silicon substrate sample subjected to 2 keV phosphorous implantation at a dose of 1 E15/cm², without post implant annealing. Before ion implantation, the sample corresponding to curve 302 was also processed with a plasma clean operation to remove native oxide and hydrogen treatment to generate hydrogen passivation on the substrate surface as generally described above. The curve 304 represents a dopant profile of a silicon substrate subjected to the same phosphorous ion implantation as the sample for curve 302, except no hydrogen treatment was performed before ion implantation in the case of curve 304. The graph of FIG. 3A plots phosphorous concentration as a function of depth. The curve 302 differs from the curve 304 in at least two aspects. For one aspect, the dopant concentration at or within a few nanometers of the surface (=0 nm depth) is higher for curve 302. For another aspect, the junction depth for curve 302 is several nanometers less than the junction depth for curve 304.

Note that this result is counterintuitive in that the sample for curve 304 by nature includes a native oxide layer or chemical oxide layer (layer regrown in ambient after semiconductor surface is cleaned) on the outer surface of the silicon substrate, as illustrated by the insert in FIG. 3A. Moreover, the thickness of this native oxide layer is estimated to be on the order of at least a nm or so. Thus, the phosphorous ions in the implant performed for the sample of curve 304 must penetrate the oxide layer before entering the silicon substrate. Note that the hydrogen passivation 116 may constitute essentially a sub-monolayer to monolayer thickness of hydrogen on the substrate surface, and should present negligible attenuation of implanting phosphorous ions due to the low mass of hydrogen and low amount of hydrogen on the surface. In various non-limiting embodiments, a hydrogen passivation 116 may constitute 50 percent to 100 percent coverage of a silicon outer surface with hydrogen, and in particular embodiments, a 50 percent to 75 percent coverage of the silicon outer surface with hydrogen.

In view of this fact, the expectation is that the junction depth for sample of curve 304 should be shallower, perhaps by a nm or more, than the junction depth of the sample of curve 302, the opposite of the observed results. Consequently, the result of the plasma clean and hydrogen treatment of the present embodiments is to unexpectedly and substantially decrease the as-implanted junction depth as compared to a substrate implanted by known procedures.

Turning to FIG. 3B, there is shown a microscopic comparison of the structure of a sample that is implanted according to the present embodiments, and a sample implanted according to a known procedure. The image on the left represents a cross-sectional transmission electron microscopy image of a silicon substrate subjected to ion implantation that is performed after a plasma clean operation to remove native oxide and hydrogen treatment to generate hydrogen passivation on the substrate surface as generally described above. The image on the right represents a cross-sectional transmission electron microscopy image of a silicon substrate subjected to ion implantation that is performed without any plasma clean or hydrogen treatment before ion implantation. In each case, a post-implantation anneal has been performed at 900° C. has been performed to recrystallized areas of the respective silicon substrates damaged by the implantation procedure. As evident in the image on the left, no visible lattice damage is present after the implantation and anneal. The image of the right exhibits within the first 20 nm or so below the outer surface of the silicon substrate. Thus, the use of an in-situ plasma clean (meaning a plasma clean in an apparatus located within the beamline ion implanter) and in-situ hydrogen treatment before ion implantation may be effective to reduce or eliminate residual damage caused by ion implantation that may otherwise be unrecoverable even after post-implantation annealing procedures are performed.

FIG. 3C presents experimental electron microscopy analysis showing the effect of processing a substrate according to the present embodiments on the solid phase epitaxial regrowth (SPER) in the substrate. The substrate in question in both left hand image and the right hand image is monocrystalline silicon substrate, upon which substrate a layer stack comprised of a low-Ge concentration crystalline SiGe buffer layer, and high Ge concentration (˜50%) crystalline layer is grown.

The left hand image presents a cross-sectional view of the above-described substrate after implantation with 3 keV Ge ions at a dose of 6 E14/cm², followed by an implant of B ions at an energy of 1 keV and a dose of 5 E15/cm². In addition, after implantation, a solid phase epitaxial anneal has been performed at 600° C., 15 seconds. As evident, there are different regions or layers present in the substrate shown. The region D represents a bulk monocrystalline silicon region; the region C represents a SiGe buffer layer; the region B represents a damaged SiGe layer; while the region A represents an amorphous SiGe layer. An initially-amorphized layer has been regrown, while certain residual damage remains, including the region A, amorphous SiGe layer, having a thickness of approximately 5 nm, and the region B, a damaged, but crystalline SiGe layer.

The right hand image presents a cross-sectional view of a substrate that is implanted the same as the substrate in the left hand image, with 3 keV Ge ions at a dose of 6 E14/cm², followed by an implant of B ions at an energy of 1 keV and a dose of 5 E15/cm². After implantation, the same solid phase epitaxial anneal has been performed at 600° C., 15 seconds. In this case, in accordance with the present embodiments, an in-situ plasma clean and hydrogen treatment to form a hydrogen passivation was performed before implantation. An initially-amorphized layer has also been regrown, with less residual damage remaining. In this case, the region A, the amorphous layer, is just approximately 2 nm, while the region B, the layer of crystalline SiGe above the buffer layer (region C) exhibits little damage. From these results, it can be estimated that, for the silicon/SiGe system shown, the use of in-situ plasma clean and hydrogen treatment of a semiconductor substrate that is subject to an amorphizing implant may improve SPER by approximately 2.5 times, in comparison to a semiconductor substrate that is subject to the same amorphizing implant without the in-situ plasma clean and hydrogen treatment. For other silicon, SiGe, or Si/SiGe systems, a similar improvement in SPER may be produced using the in-situ plasma clean and hydrogen treatment of the present embodiments;

Thus, the use of an in-situ plasma clean (meaning a plasma clean in an apparatus located within the beamline ion implanter) and hydrogen treatment before ion implantation may be effective to improve the amorphization/crystalline interface for amorphizing implants. This improved interface may allow for enhanced recrystallization rates at relatively lower temperatures (<650° C.).

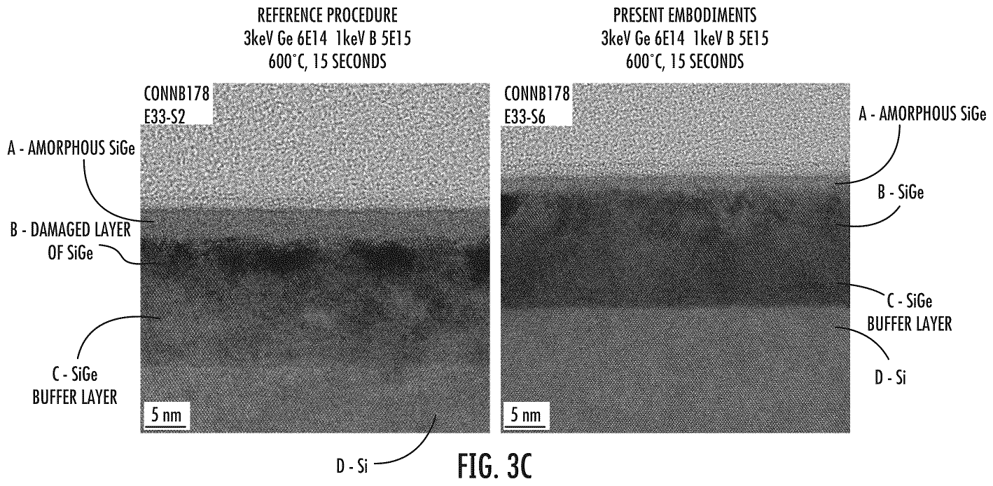

Turning to FIG. 4 there is depicted in block form the architecture of an exemplary ion implantation system, shown as ion implanter 400, according to embodiments of the disclosure. The ion implanter 400 includes an ion source 402 to generate ion beam 418 that implants the ion species 118, as described above. The ion implanter 400 may include various components to accelerate, decelerated, shape, and filter an ion beam, as known in the art. These components are depicted as beamline 404. Downstream of the beamline 404 an end station 406 is provided to house the substrate 100, during ion implantation. The ion implanter 400 may include a plasma clean chamber 408 as well as a hydrogen treatment chamber 410. These chambers may be a single chamber or may be separate chambers from one another that are communicatively coupled to the end station 406, so that the semiconductor substrate 100 may be transported between the different chambers, while being maintained under a vacuum environment to perform to processes as outlined in FIGS. 1A-1C. In other embodiments, one or more of the plasma source 110 and the plasma source 114 may be included within the end station 406. In any of these configurations of plasma chambers and ion sources, the semiconductor substrate 100 may be maintained under a vacuum condition between operations, such as plasma cleaning, hydrogen treatment, and ion implantation. Because the semiconductor substrate 100 is maintained under vacuum conditions over a duration that extends from plasma cleaning to ion implantation, the semiconductor substrate 100 may not experience the formation of native oxide, carbon contamination, or other surface contamination, at least up through the duration of the ion implantation.

Without limitation as to any particular theory, the improved defect engineering (reduction of residual substrate damage, better control of junction depth after dopant implantation, and other effects) achieved according to the present embodiments may result in part by the preservation of a semiconductor surface that has little or no native oxide disposed thereon. During an ion implantation process, many silicon interstitials are generated in the bulk of the semiconductor substrate being implanted. These silicon interstitials travel within the semiconductor substrate, even when substrate temperature is at room temperature. In the presence of native oxide, the interstitials may be reflected back, into the bulk of the semiconductor substrate, causing defectivity, deactivation, and the persistence of a high number of interstitial atoms after implantation is complete. The multi-process substrate treatment disclosed herein addresses this problem as follows. The plasma cleaning within an ion implantation apparatus results in removal of a native oxide from the surface of the semiconductor substrate, while the maintaining of the semiconductor substrate under high vacuum conditions will tend to preserve the semiconductor surface free of native oxide up to the time when dopant deposition is performed. This native-oxide-free surface may expose a rich layer of silicon dangling bonds, at least some of which bonds may be terminated with hydrogen after hydrogen treatment, which condition will enable silicon interstitials to terminate at the surface. Said differently, the annihilation rate of interstitials at the surface may be increased, leading less defectivity, higher dopant activation, less interstitial-enhanced diffusion of the dopant species, after implantation, and improved recrystallization after amorphizing implants.

As best understood, this result is accomplished due to the entire series of processes, including plasma cleaning, hydrogen treatment, and ion implantation being completed on an integrated beamline architecture that maintains the substrate under common vacuum. In this regard, after removal of an oxide layer by plasma cleaning, by performing the hydrogen treatment, the resulting hydrogen passivation, such as 50% to 100% of the outer silicon surface, will prevent or retard reaction with any ambient species, such as organics, H₂O, oxygen, etc., and thus will retard the (re)formation of any oxide layer on the silicon surface. Moreover, by maintaining the substrate under vacuum after formation of the hydrogen passivation, the flux of unwanted species, such as oxygen, H₂O, will be greatly reduced as compared to exposing the substrate to ambient conditions at one atmosphere pressure, for example. As such, the preservation of the hydrogen passivation will be greatly enhanced, such that the regrowth of an oxide layer is greatly suppressed.

According to various embodiments, the operations of FIGS. 1B-1C and the operations of FIGS. 2B-2D may be repeated in cyclical fashion to achieve a target implant dose within a substrate. In particular embodiments, the hydrogen treatment and the implant process of FIG. 1B and FIG. 1C, respectively, are performed as an implant cycle, where the implant cycle is repeated one or more times to implant a target implant dose level into the substrate. In further embodiments, the plasma clean operation, hydrogen treatment and the implant process of FIG. 2B, FIG. 2C, and FIG. 2D, respectively, are performed as another implant cycle, where this other implant cycle is repeated one or more times to implant a target implant dose level into the substrate.

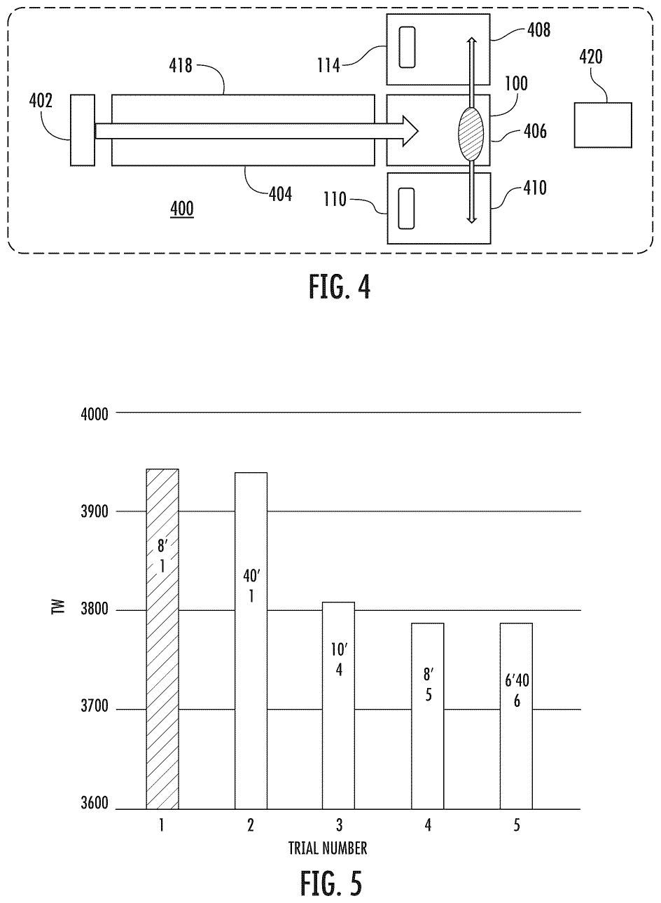

The present inventors have discovered that, for a given total implant dose of ions to be implanted into a substrate, the residual damage may be lessened by performing multiple cycles where each cycle involves hydrogen treatment followed by ion implantation, where in each cycle the substrate is exposed to just a portion of the total implant dose. FIG. 5 presents a histogram graph that depicts a comparison of residual substrate damage after ion implantation for substrates implanted with the same total ion dose, in this case 5 e14/cm² B implantation. The different bars (trial numbers) in the histogram graph represent different number of cycles performed to achieve the total ion dose, as well as different durations for hydrogen treatment. The ordinate axis depicts the relative intensity of a thermawave (TW) measurement for the different samples, where a larger value indicates greater substrate damage.

The trial number 1 bar represents the measured substrate damage after a single hydrogen treatment of 8 minutes duration, followed by a single ion implantation procedure, meaning just one cycle involving a single ion implantation process is used to implant the 5 e14/cm² B total ion dose. The trial number 2 bar represents the measured substrate damage after a single hydrogen treatment of 40 minutes duration, followed by a single ion implantation procedure. In this example, a single cycle is performed, but the hydrogen treatment duration is much longer. As is evident, the residual damage for the sample treated with hydrogen for forty minutes is slightly lower than the damage for the sample treated with hydrogen for eight minutes. Said differently, 40 minutes hydrogen treatment appears to be sufficient to achieve the lowest residual damage when a single cycle procedure (single ion implantation exposure) is to be used to implant 5 e14/cm² B total ion dose.

In a series of other trials, (trial number 3-5), multiple cycles were performed to implant the total ion dose of 5 e14/cm² B, where the total duration of hydrogen treatment across all the cycles was held constant at 40 minutes. For trial number 3, a total of four cycles were performed, with a 10 minute hydrogen treatment followed by a 1.25 e14/cm² B dose implanted in each cycle. In this trial, the TW value reduced substantially from 3940 to 3810, indicating substantially less residual damage after the total ion dose was implanted. For trial number 4, a total of five cycles were performed, with a 8 minute hydrogen treatment followed by a 1 e14/cm² B dose implanted in each cycle. In this trial, the TW value reduced somewhat from 3810 to 37865, indicating somewhat less residual damage after the total ion dose was implanted. For trial number 5, a total of six cycles were performed, with a 6 minute 40 second hydrogen treatment followed by a 8.33 e13/cm² B dose implanted in each cycle. In this trial, the TW value did not reduce from the value of 3985, indicating that the damage level was approximately the same as the trial number 4, which trial used five cycles. Thus, an ion implantation procedure according to the present embodiments may employ multiple cycles to implant a target dose into a substrate, where the partial implanted dose for a given cycle and duration of hydrogen treatment may be adjusted to minimize residual substrate damage after implantation. In this regard, and with reference again to FIG. 4, the ion implanter 400 may include a controller 420 that is coupled to at least the plasma source 110, as well as other components, such as beamline 404, and end station 406. As such, the controller 420 may direct a plurality of implant cycles, where an individual implant cycle comprises alternately exposing the substrate to the hydrogen species from the plasma source 110, and exposing the substrate to the ion beam 418.

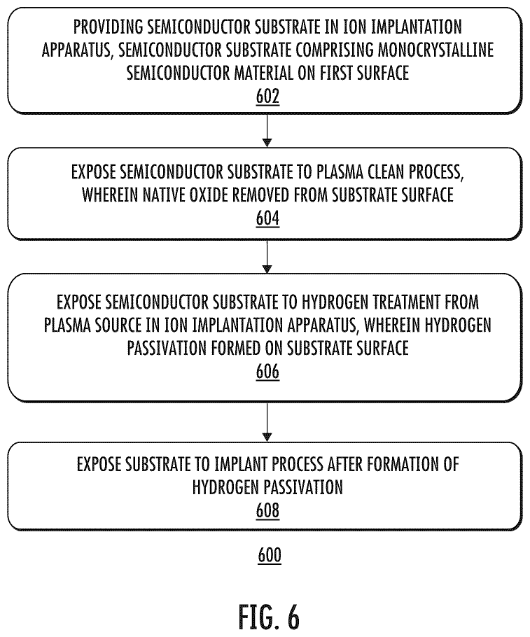

FIG. 6 provides an exemplary process flow 600, according to embodiments of the disclosure. At block 602 a semiconductor substrate is provided in an ion implantation apparatus, where the semiconductor substrate includes a monocrystalline semiconductor material on a first surface, meaning an outer surface of the semiconductor substrate.

At block 604, the semiconductor substrate is exposed to a plasma clean process while disposed in the ion implantation apparatus, wherein a native oxide is removed from the substrate surface. In some embodiments, the plasma clean operation may employ a plasma source that is located the ion implantation apparatus. The plasma source may represent any suitable apparatus to generate a plasma, and in some instances may represent a radical source. In any case, the plasma source may generate cleaning species that may represent a combination of ions and neutrals, including radicals.

At block 606 the semiconductor substrate is exposed to a hydrogen treatment from a plasma source that is disposed in the ion implantation apparatus. As such, a hydrogen passivation may be formed on the substrate surface. In various embodiments, the hydrogen treatment may be performed by directing hydrogen species at a substrate that is at a temperature below 100° C., such as between room temperature and 100° C. The hydrogen species may be generated by providing an H₂ gas for example to a plasma chamber. As such, the substrate surface may represent a ‘clean’ semiconductor surface that presents silicon species to the ambient within the ion implantation apparatus, with minimal or no foreign species such as oxygen or carbon on the substrate surface. Moreover, after removal of the native oxide, the hydrogen species may cause the substrate surface to be terminated with hydrogen that is bonded to the semiconductor substrate, to form the hydrogen passivation.

At block 608, the substrate is exposed to an implant process after formation of hydrogen passivation. In accordance with different embodiments, the implant process may be a dopant implant process, a pre-amorphization implant process, or other implant process.

In view of the above, the present embodiments convey the following advantages. As a first advantage, the substrate defects, such as interstitial damage that is generated by implantation is reduced in comparison to known implantation procedures that lack an in-situ hydrogen treatment of the substrate and plasma cleaning of the substrate in advance of beamline ion implantation. This reduced damage may be reflected both in a shallower implant profile for implanted dopants, as well as higher surface concentration of dopant. Another advantage of the present embodiments is that this reduced damage may be preserved even after post-implantation annealing, as evidenced by the defect-free lattice after recrystallization. In particular, embodiments of the present disclosure may improve solid phase epitaxial regrowth that takes place as a result of post-implantation annealing by performing an in-situ plasma clean and hydrogen treatment.

‡ The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are in the tended to fall within the scope of the present disclosure. Furthermore, while the present disclosure has been described herein in the context of a particular implementation in a particular environment for a particular purpose, those of ordinary skill in the art will recognize the usefulness of the present embodiments is not limited thereto and the present embodiments may be beneficially implemented in any number of environments for any number of purposes. Thus, the claims set forth below are to be construed in view of the full breadth and spirit of the present disclosure as described herein.

What is claimed is:

1. A method of treating a semiconductor substrate, comprising, in a beamline ion implanter:
exposing a substrate surface of the semiconductor substrate to a plasma clean;
exposing the substrate surface to a hydrogen treatment from a plasma source; and
exposing the semiconductor substrate to an implant process after the hydrogen treatment,
wherein the semiconductor substrate is maintained under vacuum over a process duration spanning the plasma clean, the hydrogen treatment, and the implant process.

2. The method of claim 1, comprising:
wherein the implant process comprises introducing a dopant element into the semiconductor substrate.

3. The method of claim 2, wherein the implant process comprises an amorphizing implant that generates an amorphous layer in the semiconductor substrate, the method further comprising:
annealing the semiconductor substrate at a temperature of 650° C. or less, wherein a solid phase epitaxial regrowth of the amorphous layer takes place.

4. The method of claim 1, wherein the implant process comprises a pre amorphizing implant, the method further comprising performing a dopant implant process to introduce a dopant into the semiconductor substrate after the pre amorphizing implant.

5. The method of claim 1, wherein the substrate surface includes a native oxide, before the plasma clean, and wherein the native oxide is removed after the plasma clean.

6. The method of claim 5, wherein the plasma clean comprises:
removing the native oxide by plasma etching; and
exposing the substrate surface to the hydrogen treatment after the native oxide is removed.

7. The method of claim 1, wherein the hydrogen treatment comprises:
generating a hydrogen species in a plasma chamber; and
directing the hydrogen species to the substrate surface when the semiconductor substrate is at a treatment temperature below 100° C.,
wherein the substrate surface is terminated with a hydrogen passivation after the plasma clean.

8. The method of claim 1, wherein the plasma clean comprises a cleaning species having an energy less than or equal to 50 eV, and the hydrogen treatment comprises a hydrogen species having an energy less than or equal to 50 eV.

9. The method of claim 1, wherein the hydrogen treatment and the implant process are performed as an implant cycle, wherein the implant cycle is repeated one or more times to implant a target implant dose level into the semiconductor substrate.

10. The method of claim 1, wherein the plasma clean, the hydrogen treatment and the implant process are performed as an implant cycle, wherein the implant cycle is repeated one or more times to implant a target implant dose level into the semiconductor substrate.

11. A method of doping a substrate, comprising:
providing a monocrystalline semiconductor material on a substrate surface of the substrate;
exposing the substrate surface to a hydrogen treatment from a plasma source a beamline ion implanter; and
exposing the substrate to an implant process in the beamline ion implanter after the hydrogen treatment,
wherein the implant process introduces a dopant species into the substrate, and
wherein the substrate is maintained under vacuum over a process duration spanning the hydrogen treatment, and the implant process.

12. The method of claim 11, wherein the implant process comprises a pre-amorphizing implant, the method further comprising performing a dopant implant process to introduce a dopant into the substrate after the pre-amorphizing implant.

13. The method of claim 11, wherein the substrate surface includes a native oxide, before the hydrogen treatment, and wherein the native oxide is removed after the hydrogen treatment.

14. The method of claim 13, further comprising:
removing the native oxide by a plasma etching process from a plasma etch source before the hydrogen treatment.

15. The method of claim 14, wherein the hydrogen treatment removes the native oxide and provides a hydrogen passivation on the substrate surface after the plasma etching process.

16. The method of claim 11, wherein the hydrogen treatment comprises:
generating a hydrogen species in a plasma chamber; and
directing the hydrogen species to the substrate surface when the substrate is at a treatment temperature below 100° C., wherein the hydrogen species have an energy less than or equal to 50 eV.
wherein the substrate surface is terminated with a hydrogen passivation after the hydrogen treatment.

17. The method of claim 11, wherein the hydrogen treatment and the implant process are performed as an implant cycle, wherein the implant cycle is repeated one or more times to implant a target implant dose level into the substrate.

18. A beamline ion implantation system, comprising:
an ion source, to generate an ion beam;
a beamline to conduct the ion beam to an end station;
a substrate platen to support a substrate while in the end station; and
a plasma source, communicatively coupled with the end station and arranged to direct a hydrogen species to the substrate.

19. The beamline ion implantation system of claim 18, the plasma source being disposed in the end station.

20. The beamline ion implantation system of claim 18, further comprising a controller to direct a plurality of implant cycles, wherein the plurality of implant cycles comprises: alternately exposing the substrate to the hydrogen species from the plasma source, and exposing the substrate to the ion beam.
